(19) United States
(12) Patent Application Publication
(10) Pub. No.: US 2016/0230271 A1
(43) Pub. Date: Aug. 11, 2016

(54) HEATING VESSEL FOR PREVENTING LEAKAGE OF HIGH TEMPERATURE METAL MATERIAL AND MANUFACTURE METHOD THEREOF

(71) Applicant: SHENZHEN CHINA STAR OPTOELECTRONICS TECHNOLOGY CO. LTD., Shenzhen, Guangdong (CN)

(72) Inventors: Youyuan KUANG, Shenzhen, Guangdong (CN); Qinghua ZOU, Shenzhen, Guangdong (CN); Xindi ZHANG, Shenzhen, Guangdong (CN); Taipi WU, Shenzhen, Guangdong (CN); Tsungyuan WU, Shenzhen, Guangdong (CN)

(73) Assignee: Shenzhen China Star Optoelectronics Technology Co. Ltd., Shenzhen, Guangdong (CN)

(21) Appl. No.: 14/381,194

(22) PCT Filed: May 28, 2014
(86) PCT No.: PCT/CN2014/078676

§ 371 Date: Aug. 26, 2014

(30) Foreign Application Priority Data
May 14, 2014 (CN) 201410204621.1

(51) Int. Cl. C23C 16/02; C23C 16/455; C23C 16/06

(52) U.S. Cl. CPC C23C 16/0209; C23C 16/06; C23C 16/45563

(57) ABSTRACT

The present invention is related with a heating vessel for preventing leakage of high temperature metal material and a manufacture method thereof. The heating vessel comprises: an internal heating vessel employed for containing metal material, an external heating vessel employed to be heated by a heating apparatus and a top cap having a vapor hole employed for escape of the vaporized metal material; the internal heating vessel is completely contained in the external heating vessel and positionally fixed relative to the external heating vessel, and an interspace exists between a side wall of the internal heating vessel and a side wall of the external heating vessel, and the top cap is fixed on tops of the internal heating vessel and the external heating vessel to cover opens of the internal heating vessel and the external heating vessel. The present invention also provides the manufacture method of the vessel. The present invention overcomes the issues of the material abnormal loss and production progress interruption due to the appeared fracture in daily usages. The continuous steady running period of the heating apparatus is effectively promoted and the quality of the production is guaranteed.

### FIELD OF THE INVENTION

The present invention relates to a heating vessel, and more particularly to a heating vessel for preventing leakage of high temperature metal material and a manufacture method thereof.

### BACKGROUND OF THE INVENTION

OLED (Organic Light Emitting Diode) possesses advantages of being all-solid state, ultra thin, no view angle limited, fast responding, room temperature workable, easy achievable flexible displaying and 3D displaying. It is supposed to be the main stream technology of next generation display. At present, heating vapor coating is a main manufacture way of the OLED elements. The coating material is heated in vacuum by using a heating vessel. The vapor coating material which is sublimable or fusable is vaporized under the high temperature circumstance and deposited on a substrate having TFT compositions or anode compositions.

During the present vapor deposition according to prior arts, a single layer vessel is commonly utilized as the vaporization vessel to be heated for vaporization. Nevertheless, micro cracks appear so common at the joint of the lateral side and the bottom of the heating vessel caused by condensation and shrinkage of the high temperature metal liquid and then material abnormal loss happens. Moreover, the high temperature liquid may outflow from the micro cracks and into the heating apparatus to lead to the internal short circuit and damage to the whole heating apparatus. Consequently, the OLED production progress is interrupted and the production quality descends. The fracture and leakage of the heating vessel are very difficult to be confirmed and hard to predict because the micro cracks are not easy to be found under the cooling status.

Please refer to FIG. 1A and FIG. 1B. FIG. 1A is a structure diagram of an OLED heating vessel according to prior art. FIG. 1B is a sectional diagram of FIG. 1A. The OLED heating vessel is utilized in the OLED vapor deposition process in prior arts. A top cap 2 is positioned on the top of the heating vessel. The top cap 2 comprises a vapor hole 1. The material 3 contained in the heating vessel is heated up and vaporized. Then, it can escape from the vapor hole 1 as indicated by the arrows. When the heating vessel is damaged, the material 3 may leak from the fractures 4 and flow into the heating apparatus. The material 3 can be massively lost and the vaporized rate may drop to interrupt the production progress. Meanwhile, without being aware, the material 3 is possible to be filled and gets into the heating apparatus. There will be possibility to result the damages to the heating apparatus.

### SUMMARY OF THE INVENTION

Therefore, an objective of the present invention is to provide a heating vessel for preventing leakage of high temperature metal material to overcome the issue of the material loss due to the heating vessel damage and to protect the heating apparatus.

Another objective of the present invention is to provide a manufacture method of the heating vessel for preventing leakage of high temperature metal material to make the heating vessel to overcome the issue of the material loss due to the heating vessel damage and to protect the heating apparatus.

For realizing the aforesaid objective, the present invention provides a heating vessel for preventing leakage of high temperature metal material, comprising: an internal heating vessel employed for containing metal material, an external heating vessel employed to be heated by a heating apparatus and a top cap having a vapor hole employed for escape of the vaporized metal material; the internal heating vessel is completely contained in the external heating vessel and positionally fixed relative to the external heating vessel, and an interspace exists between a side wall of the internal heating vessel and a side wall of the external heating vessel, and the top cap is fixed on tops of the internal heating vessel and the external heating vessel to cover opens of the internal heating vessel and the external heating vessel.

Material of the internal heating vessel and material of the external heating vessel are the same.

The heating vessel is employed as a heating vessel in an OLED vapor deposition.

A bottom of the internal heating vessel and a bottom of the external heating vessel contact with each other.

An interspace exists between a bottom of the internal heating vessel and a bottom of the external heating vessel.

The internal heating vessel and the external heating vessel are crucibles.

The tops of the internal heating vessel and the external heating vessel are welded as one body.

The top cap is chucked and fixed with the tops of the internal heating vessel and the external heating vessel at the same time.

The present invention also provides a heating vessel for preventing leakage of high temperature metal material, comprising: an internal heating vessel employed for containing metal material, an external heating vessel employed to be heated by a heating apparatus and a top cap having a vapor hole employed for escape of the vaporized metal material; the internal heating vessel is completely contained in the external heating vessel and positionally fixed relative to the external heating vessel, and an interspace exists between a side wall of the internal heating vessel and a side wall of the external heating vessel, and the top cap is fixed on tops of the internal heating vessel and the external heating vessel to cover opens of the internal heating vessel and the external heating vessel;

wherein material of the internal heating vessel and material of the external heating vessel are the same;

wherein the heating vessel is employed as a heating vessel in an OLED vapor deposition;

wherein the internal heating vessel and the external heating vessel are crucibles.

A bottom of the internal heating vessel and a bottom of the external heating vessel contact with each other.

An interspace exists between a bottom of the internal heating vessel and a bottom of the external heating vessel.

The tops of the internal heating vessel and the external heating vessel are welded as one body.

The top cap is chucked and fixed with the tops of the internal heating vessel and the external heating vessel at the same time.

The present invention also provides a manufacture method of the heating vessel, comprising:

Step 1, measuring an outer dimension and an inner dimension of an internal heating vessel;

Step 2, selecting an external heating vessel which an inner dimension is capable of covering the internal heating vessel;

Step 3, lowering a height of the external heating vessel according to a height of the internal heating vessel;

Step 4, completely containing the internal heating vessel in the external heating vessel and positionally fixing the internal heating vessel relative to the external heating vessel.

The present invention also provides another manufacture method of the heating vessel, comprising:

Step 11, measuring an outer dimension and an inner dimension of an external heating vessel;

Step 21, selecting an internal heating vessel which an outer dimension is capable of to be contained in the external heating vessel;

Step 31, lowering a height of the internal heating vessel according to a height of the external heating vessel;

Step 41, completely containing the internal heating vessel in the external heating vessel and positionally fixing the internal heating vessel relative to the external heating vessel.

In conclusion, the heating vessel for preventing leakage of high temperature metal material of the present invention overcomes the issues of the material abnormal loss and production progress interruption due to the appeared fracture in daily usages. The continuous steady running period of the heating apparatus is effectively promoted and the quality of the production is guaranteed; meanwhile, the manufacture method of the heating vessel is convenient and fast, and the cost is low.

### BRIEF DESCRIPTION OF THE DRAWINGS

The technical solution, as well as beneficial advantages, of the present invention will be apparent from the following detailed description of an embodiment of the present invention, with reference to the attached drawings.

In the attached drawings,

FIG. 1A is a structure diagram of an OLED heating vessel according to prior art;

FIG. 1B is a sectional diagram of FIG. 1A;

FIG. 2 is a sectional diagram of a heating vessel for preventing leakage of high temperature metal material according to the first preferable embodiment of the present invention;

FIG. 3 is a sectional diagram of a heating vessel for preventing leakage of high temperature metal material according to the second preferable embodiment of the present invention;

FIG. 4 is a sectional diagram of a heating vessel for preventing leakage of high temperature metal material according to the third preferable embodiment of the present invention;

FIG. 5 is a sectional diagram of a heating vessel for preventing leakage of high temperature metal material according to the fourth preferable embodiment of the present invention;

FIG. 6 is a sectional diagram of a heating vessel for preventing leakage of high temperature metal material according to the fifth preferable embodiment of the present invention;

FIG. 7 is a sectional diagram of a heating vessel for preventing leakage of high temperature metal material according to the sixth preferable embodiment of the present invention;

FIG. 8 is a sectional diagram of a heating vessel for preventing leakage of high temperature metal material according to the seventh preferable embodiment of the present invention;

FIG. 9 is a sectional diagram of a heating vessel for preventing leakage of high temperature metal material according to the eighth preferable embodiment of the present invention.

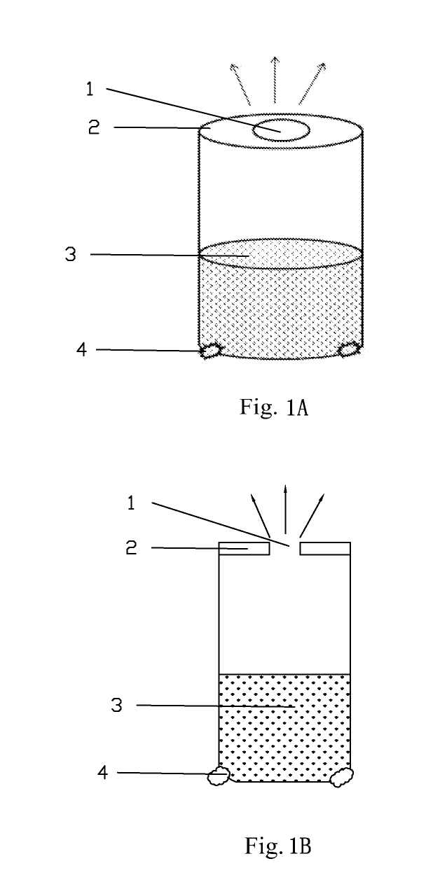

### DETAILED DESCRIPTION OF PREFERRED EMBODIMENTS

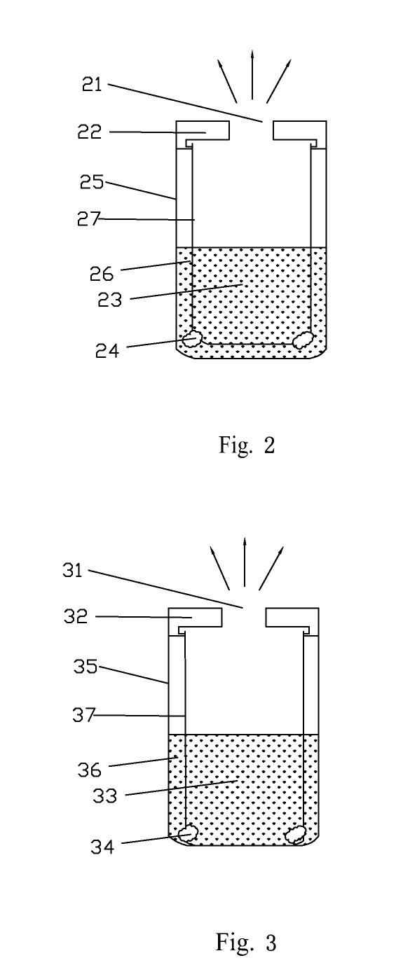

Please refer to FIG. 2, which shows a sectional diagram of a heating vessel for preventing leakage of high temperature metal material according to the first preferable embodiment of the present invention. In this and the following embodiments, cylinder-shaped heating vessels are illustrated and the sectional diagram is made along the diameter direction of the cylinders. The eating vessel for preventing leakage of high temperature metal material of this preferable embodiment comprises: an internal heating vessel 27 employed for containing metal material, an external heating vessel 25 employed to be heated by a heating apparatus and a top cap 22 having a vapor hole 21 employed for escape of the vaporized metal material; the internal heating vessel 27 is completely contained in the external heating vessel 25 and positionally fixed relative to the external heating vessel 25, and an interspace exists between a side wall of the internal heating vessel 27 and a side wall of the external heating vessel 25, and the top cap 22 is fixed on tops of the internal heating vessel 27 and the external heating vessel 25 to cover opens of the internal heating vessel 27 and the external heating vessel 25.

The heating vessel is employed as a heating vessel in an OLED vapor deposition. The internal part and the external part of the heating vessel can be made by the same material but different in dimension. The internal heating vessel 27 and the external heating vessel are crucibles 25, wherein the tops thereof are not welded but merely chucked with the top cap 22. The top cap 22 can be a buckle structure for buckling the upper edges of the internal heating vessel 27 and the external heating vessel 25. The top cap 22 has a vapor hole 21 in center, employed for escape of the vaporized material 23. Bottoms of the two vessels do not contact with each other. The heating apparatus heats up the external heating vessel 25. The external heating vessel 25 conducts the heat to the internal heating vessel 27 by irradiation. The material 23 is contained only in the internal heating vessel 27. As the internal heating vessel 27 is heated up, the material 23 is vaporized. The vapor of the material 23 escapes from the vapor hole 21 of the top cap 22. When the internal heating vessel 27 is damaged and fractures 24 appear, both the material 23 in the internal heating vessel 27 and leaked material 26 in the interspace are vaporized and escape from the vapor hole 21.

The aforesaid OLED vapor deposition device can maintain the normal production progress under the circumstance that the internal heating vessel is damaged with the improvement of the heating vessel. The material abnormal loss and the damage to the heating apparatus do not happen. The double layer OLED material vaporizing vessel efficiently reduces the risk of material loss due to the damage of the vessel and prevents the risk of the damage to the heating apparatus. Moreover, the continuous steady running period of the heating apparatus is increased.

With the improvement of the traditional heating vessel according to the present invention, a present single layer Bessel is improved to be a double layer heating vessel. When the damages and fractures appear at the joint of the heating vessel, the material leakage and loss can be efficiently controlled and the entire heating apparatus can be protected. The quality and the progress of the production can be guaranteed.

Please refer to FIG. 3, which is a sectional diagram of a heating vessel for preventing leakage of high temperature metal material according to the second preferable embodiment of the present invention. The heating vessel comprises the internal heating vessel 37 and the external heating vessel 35 which are made by the same material, wherein the tops thereof are not welded but merely chucked with the top cap 32. The top cap 32 has a vapor hole 31 in center, employed for escape of the vaporized material 33. Bottoms of the two vessels contact with each other. The heating apparatus heats up the external heating vessel 35. The external heating vessel 35 conducts the heat to the side wall of the internal heating vessel 37 by irradiation and conducts the heat to the internal heating vessel 37 through the bottoms. As the internal heating vessel 37 is heated up, the material 33 is vaporized. The vapor of the material 33 escapes from the vapor hole 31 of the top cap 32. When the internal heating vessel 37 is damaged and fractures 34 appear, both the material 33 in the internal heating vessel 37 and leaked material 36 in the interspace are vaporized and escape from the vapor hole 31.

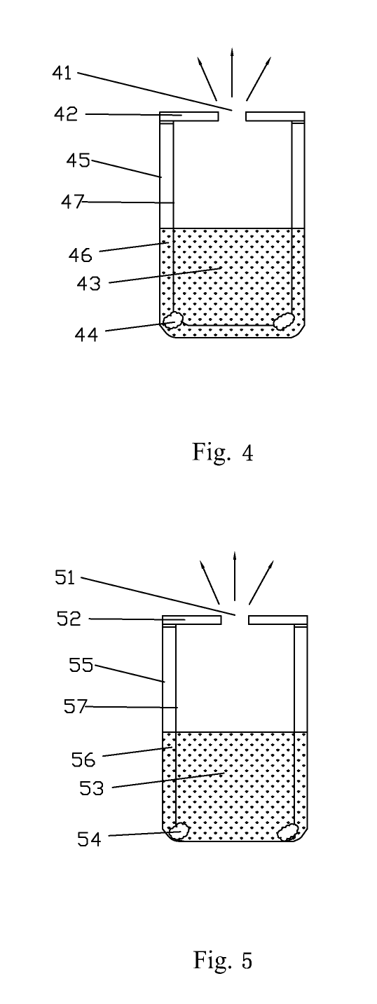

Please refer to FIG. 4, which is a sectional diagram of a heating vessel for preventing leakage of high temperature metal material according to the third preferable embodiment of the present invention. The heating vessel comprises the internal heating vessel 47 and the external heating vessel 45 which are made by the same material, wherein the tops thereof are welded and bottoms of the two vessels do not contact with each other. The heating apparatus heats up the external heating vessel 45. The external heating vessel 45 conducts the heat to the internal heating vessel 47 by irradiation. As the internal heating vessel 47 is heated up, the material 43 is vaporized. The vapor of the material 43 escapes from the vapor hole 41 of the top cap 42. When the internal heating vessel 47 is damaged and fractures 44 appear, only the material 43 in the internal heating vessel 47 is vaporized and escapes from the vapor hole 41. The leaked material 46 is kept in the intersapce.

Please refer to FIG. 5, which is a sectional diagram of a heating vessel for preventing leakage of high temperature metal material according to the fourth preferable embodiment of the present invention. The heating vessel comprises the internal heating vessel 57 and the external heating vessel 55 which are made by the same material, wherein the tops thereof are welded and bottoms of the two vessels contact with each other. The heating apparatus heats up the external heating vessel 55. The external heating vessel 55 conducts the heat to the side wall of the internal heating vessel 57 by irradiation and conducts the heat to the internal heating vessel 57 through the bottoms. As the internal heating vessel 57 is heated up, the material 53 is vaporized. The vapor of the material 53 escapes from the vapor hole 51 of the top cap 52. When the internal heating vessel 57 is damaged and fractures 54 appear, only the material 53 in the internal heating vessel 57 is vaporized and escapes from the vapor hole 51. The leaked material 56 is kept in the intersapce.

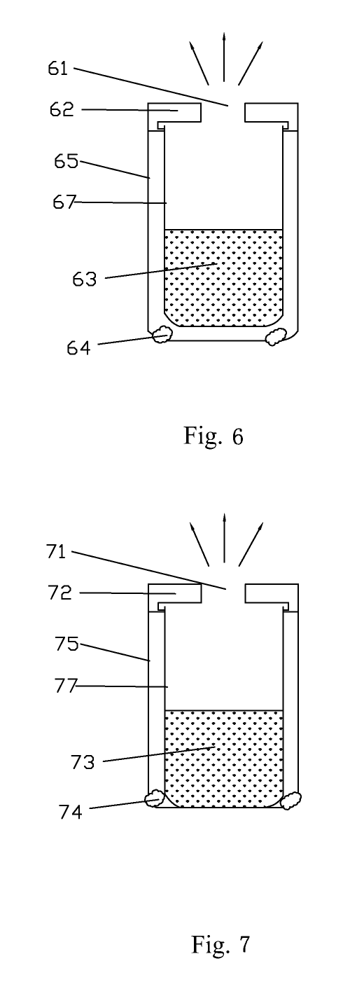

Please refer to FIG. 6, which is a sectional diagram of a heating vessel for preventing leakage of high temperature metal material according to the fifth preferable embodiment of the present invention. The heating vessel comprises the internal heating vessel 67 and the external heating vessel 65 which are made by the same material, wherein the tops thereof are not welded but merely chucked with the top cap 62. The top cap 62 has a vapor hole 61 in center, employed for escape of the vaporized material 63. Bottoms of the two vessels do not contact with each other. The heating apparatus heats up the external heating vessel 65. The external heating vessel 65 conducts the heat to the internal heating vessel 67 by irradiation. As the internal heating vessel 67 is heated up, the material 63 is vaporized. The vapor of the material 63 escapes from the vapor hole 61 of the top cap 62. When the internal heating vessel 67 is damaged and fractures 64 appear, the material 63 in the internal heating vessel 67 is vaporized and escapes from the vapor hole 61.

Please refer to FIG. 7, which is a sectional diagram of a heating vessel for preventing leakage of high temperature metal material according to the sixth preferable embodiment of the present invention. The heating vessel comprises the internal heating vessel 77 and the external heating vessel 75 which are made by the same material, wherein the tops thereof are not welded but merely chucked with the top cap 72. The top cap 72 has a vapor hole 71 in center, employed for escape of the vaporized material 73. Bottoms of the two vessels contact with each other. The heating apparatus heats up the external heating vessel 75. The external heating vessel 75 conducts the heat to the side wall of the internal heating vessel 77 by irradiation and conducts the heat to the internal heating vessel 77 through the bottoms. As the internal heating vessel 77 is heated up, the material 73 is vaporized. The vapor of the material 73 escapes from the vapor hole 71 of the top cap 72. When the internal heating vessel 77 is damaged and fractures 74 appear, the material 73 in the internal heating vessel 77 are vaporized and escapes from the vapor hole 71.

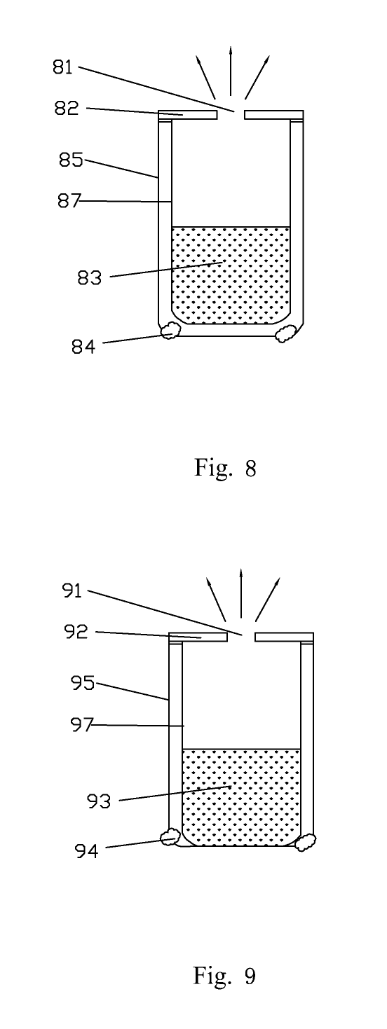

Please refer to FIG. 8, which is a sectional diagram of a heating vessel for preventing leakage of high temperature metal material according to the seventh preferable embodiment of the present invention. The heating vessel comprises the internal heating vessel 87 and the external heating vessel 85 which are made by the same material, wherein the tops thereof are welded and bottoms of the two vessels do not contact with each other. The heating apparatus heats up the external heating vessel 85. The external heating vessel 85 conducts the heat to the internal heating vessel 87 by irradiation. As the internal heating vessel 87 is heated up, the material 83 is vaporized. The vapor of the material 83 escapes from the vapor hole 81 of the top cap 82. When the internal heating vessel 87 is damaged and fractures 84 appear, only the material 83 in the internal heating vessel 87 is vaporized and escapes from the vapor hole 81.

Please refer to FIG. 9, which is a sectional diagram of a heating vessel for preventing leakage of high temperature metal material according to the eighth preferable embodiment of the present invention. The heating vessel comprises the internal heating vessel 97 and the external heating vessel 95 which are made by the same material, wherein the tops thereof are welded and bottoms of the two vessels contact with each other. The heating apparatus heats up the external heating vessel 95. The external heating vessel 39 conducts the heat to the side wall of the internal heating vessel 97 by irradiation and conducts the heat to the internal heating vessel 97 through the bottoms. As the internal heating vessel 97 is heated up, the material 93 is vaporized. The vapor of the material 93 escapes from the vapor hole 91 of the top cap 92. When the internal heating vessel 97 is damaged and fractures 94 appear, only the material 93 in the internal heating vessel 97 is vaporized and escapes from the vapor hole 91.

The present invention also provides a manufacture method in accordance with the heating vessel, comprising:

Step 1, measuring an outer dimension and an inner dimension of an internal heating vessel;

Step 2, selecting an external heating vessel which an inner dimension is capable of covering the internal heating vessel;

Step 3, lowering a height of the external heating vessel according to a height of the internal heating vessel; after lowering the height of the external heating vessel, the top of the external heating vessel is aligned with the top of the internal heating vessel horizontally.

Step 4, completely containing the internal heating vessel in the external heating vessel and positionally fixing the internal heating vessel relative to the external heating vessel; the top portions of the two vessels can be melted and welded as one body. Alternatively, the top cap can be utilized to be chucked to fix the internal heating vessel and the external heating vessel positionally relative to each other.

After the manufacture is accomplished, the proper material can be put in the heating apparatus to be heated up; the thickness parameters are calibrated according to the vapor deposition process. The manufactured heating vessel overcomes the issue of the material loss due to the heating vessel damage and to protect the heating apparatus at the same time.

Another provided manufacture method comprises:

Step 11, measuring an outer dimension and an inner dimension of an external heating vessel;

Step 21, selecting an internal heating vessel which an outer dimension is capable of to be contained in the external heating vessel;

Step 31, lowering a height of the internal heating vessel according to a height of the external heating vessel; after lowering the height of the internal heating vessel, the top of the internal heating vessel is aligned with the top of the external heating vessel horizontally.

Step 41, completely containing the internal heating vessel in the external heating vessel and positionally fixing the internal heating vessel relative to the external heating vessel; the top portions of the two vessels can be melted and welded as one body. Alternatively, the top cap can be utilized to be chucked to fix the internal heating vessel and the external heating vessel positionally relative to each other.

After the manufacture is accomplished, the proper material can be put in the heating apparatus to be heated up; the thickness parameters are calibrated according to the vapor deposition process.

By utilizing the double layer design for the heating vessel, the heating vessel for preventing leakage of high temperature metal material of the present invention overcomes the issues of the material abnormal loss and production progress interruption due to the appeared fracture in daily usages. The continuous steady running period of the heating apparatus is effectively promoted and the quality of the production is guaranteed; meanwhile, the manufacture method of the heating vessel is convenient and fast, and the cost is low.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A heating vessel for preventing leakage of high temperature metal material, comprising: an internal heating vessel employed for containing metal material, an external heating vessel employed to be heated by a heating apparatus and a top cap having a vapor hole employed for escape of the vaporized metal material; the internal heating vessel is completely contained in the external heating vessel and positionally fixed relative to the external heating vessel, and an interspace exists between a side wall of the internal heating vessel and a side wall of the external heating vessel, and the top cap is fixed on tops of the internal heating vessel and the external heating vessel to cover opens of the internal heating vessel and the external heating vessel.

2. The heating vessel for preventing leakage of high temperature metal material according to claim 1, wherein material of the internal heating vessel and material of the external heating vessel are the same.

3. The heating vessel for preventing leakage of high temperature metal material according to claim 1, wherein the heating vessel is employed as a heating vessel in an OLED vapor deposition.

4. The heating vessel for preventing leakage of high temperature metal material according to claim 1, wherein a bottom of the internal heating vessel and a bottom of the external heating vessel contact with each other.

5. The heating vessel for preventing leakage of high temperature metal material according to claim 1, wherein an interspace exists between a bottom of the internal heating vessel and a bottom of the external heating vessel.

6. The heating vessel for preventing leakage of high temperature metal material according to claim 1, wherein the internal heating vessel and the external heating vessel are crucibles.

7. The heating vessel for preventing leakage of high temperature metal material according to claim 1, wherein the tops of the internal heating vessel and the external heating vessel are welded as one body.

8. The heating vessel for preventing leakage of high temperature metal material according to claim 1, wherein the top cap is chucked and fixed with the tops of the internal heating vessel and the external heating vessel at the same time.

9. A heating vessel for preventing leakage of high temperature metal material, comprising: an internal heating vessel employed for containing metal material, an external heating vessel employed to be heated by a heating apparatus and a top cap having a vapor hole employed for escape of the vaporized metal material; the internal heating vessel is completely contained in the external heating vessel and positionally fixed relative to the external heating vessel, and an interspace exists between a side wall of the internal heating vessel and a side wall of the external heating vessel, and the top cap is fixed on tops of the internal heating vessel and the external heating vessel to cover opens of the internal heating vessel and the external heating vessel;
wherein material of the internal heating vessel and material of the external heating vessel are the same;
wherein the heating vessel is employed as a heating vessel in an OLED vapor deposition;
wherein the internal heating vessel and the external heating vessel are crucibles.

10. The heating vessel for preventing leakage of high temperature metal material according to claim 9, wherein a bottom of the internal heating vessel and a bottom of the external heating vessel contact with each other.

11. The heating vessel for preventing leakage of high temperature metal material according to claim 9, wherein an interspace exists between a bottom of the internal heating vessel and a bottom of the external heating vessel.

12. The heating vessel for preventing leakage of high temperature metal material according to claim 9, wherein the tops of the internal heating vessel and the external heating vessel are welded as one body.

13. The heating vessel for preventing leakage of high temperature metal material according to claim 9, wherein the top cap is chucked and fixed with the tops of the internal heating vessel and the external heating vessel at the same time.

14. A manufacture method of the heating vessel according to claim 1, comprising:
Step 1, measuring an outer dimension and an inner dimension of an internal heating vessel;
Step 2, selecting an external heating vessel which an inner dimension is capable of covering the internal heating vessel;
Step 3, lowering a height of the external heating vessel according to a height of the internal heating vessel;
Step 4, completely containing the internal heating vessel in the external heating vessel and positionally fixing the internal heating vessel relative to the external heating vessel.

15. The manufacture method according to claim 14, comprising:
Step 11, measuring an outer dimension and an inner dimension of an external heating vessel;
Step 21, selecting an internal heating vessel which an outer dimension is capable of to be contained in the external heating vessel;
Step 31, lowering a height of the internal heating vessel according to a height of the external heating vessel;
Step 41, completely containing the internal heating vessel in the external heating vessel and positionally fixing the internal heating vessel relative to the external heating vessel.
